(19) United States
(12) Patent Application Publication
(10) Pub. No.: US 2026/0247705 A1
(43) Pub. Date: Aug. 20, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Chia-Chien KUANG, Hsinchu (TW); Fang-Wei LEE, Hsinchu (TW); Wei Ting WANG, Hsinchu (TW); Kuan-Ting PAN, Hsinchu (TW)

(73) Assignee: Taiwan Semiconductor Manufacturing Company, Ltd., Hsinchu (TW)

(21) Appl. No.: 19/053,614

(22) Filed: Feb. 14, 2025

(51) Int. Cl. H10D 84/85; H10D 64/01; H10D 64/27; H10D 84/01

(52) U.S. Cl. CPC H10D 84/852; H10D 64/017; H10D 64/518; H10D 84/0153; H10D 84/0188

(57) ABSTRACT

A semiconductor device includes a first channel region, a second channel region, and a dielectric structure. The first channel region extends over a semiconductor substrate. The second channel region extends over the semiconductor substrate and is parallel to the first channel region in a first direction. The dielectric structure is disposed between the first and second channel regions, wherein the dielectric structure comprises a dielectric wall and wall spacers, the wall spacers are disposed on opposite sides of the dielectric wall and connected to the first channel region and the second channel region, respectively.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5, 6A, 6B, 6C, 7A, 7B, 7C, 8A, 8B, 8C, 9A, 9B, 9C, 10A, 10B, 11A, 11B, 12, 13, 14, 15, 16, 17, 18, and 19 are cross-sectional views of intermediate stages in the manufacturing of nano-FETs, in accordance with some embodiments.

FIG. 20 illustrates an example of a nanostructure field-effect transistor (nano-FET) in a three-dimensional view, in accordance with some embodiments.

FIGS. 21A and 21B illustrate an example of nano-FETs of FIG. 20 in a three-dimensional view and a top view, respectively.

FIGS. 22A and 22B illustrate another example of nano-FETs of FIG. 20 in a three-dimensional view and a top view, respectively.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments discussed herein are described in the context of a die including nano-FETs. However, various embodiments may be applied to dies including other types of transistors (e.g., fin field effect transistors (FinFETs), planar transistors, or the like) in lieu of or in combination with the nano-FETs.

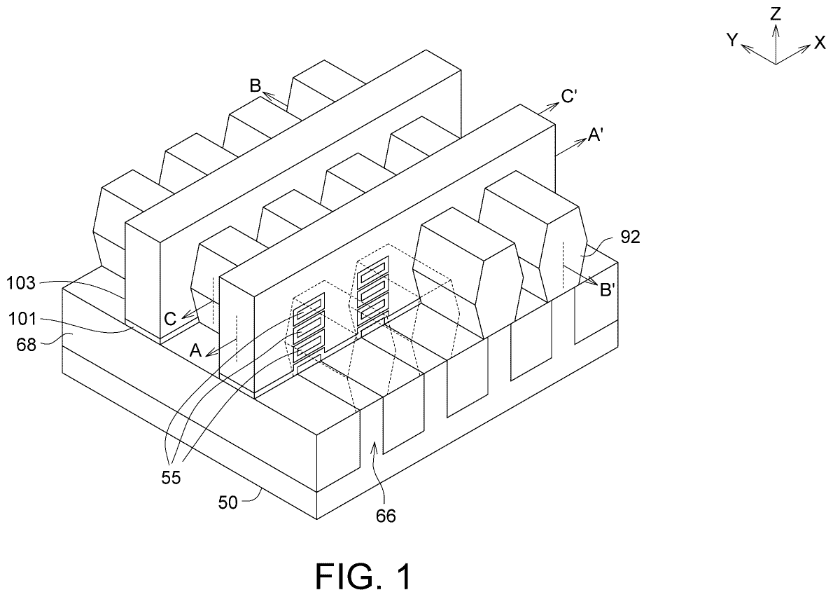

FIG. 1 illustrates an example of nano-FETs (e.g., nanowire FETs, nanosheet FETs, or the like) in a three-dimensional view, in accordance with some embodiments. The nano-FETs comprise nanostructures 55 (e.g., nanosheets, nanowire, or the like) over fins 66 on a substrate 50 (e.g., a semiconductor substrate), wherein the nanostructures 55 act as channel regions for the nano-FETs. The nanostructures 55 may include p-type nanostructures, n-type nanostructures, or a combination thereof. Shallow trench isolation (STI) regions 68 are disposed between adjacent fins 66, which may protrude above and form between neighboring STI regions 68. Although the STI regions 68 are described/illustrated as being separate from the substrate 50, as used herein, the term “substrate” may refer to the semiconductor substrate alone or a combination of the semiconductor substrate and the STI regions. Additionally, although bottom portions of the fins 66 are illustrated as being single, continuous materials with the substrate 50, the bottom portions of the fins 66 and/or the substrate 50 may comprise a single material or a plurality of materials. In this context, the fins 66 refer to the portion extending between the neighboring STI regions 68.

Gate dielectric layers 101 extend along top surfaces and side surfaces of the fins 66 and along top surfaces, side surfaces, and bottom surfaces of the nanostructures 55. Gate electrodes 103 are over the gate dielectric layers 101. Epitaxial source/drain regions 92 are disposed on the fins 66 on opposing sides of the gate dielectric layers 101 and the gate electrodes 103.

FIG. 1 further illustrates reference cross-sections that are used in later figures. Cross-section A-A′ is along a longitudinal axis of a gate electrode 103 and in a direction, for example, perpendicular to the direction of current flow between the epitaxial source/drain regions 92 of a nano-FET. Cross-section C-C′ is parallel to cross-section A-A′ and extends through epitaxial source/drain regions 92 of multiple nano-FETs. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

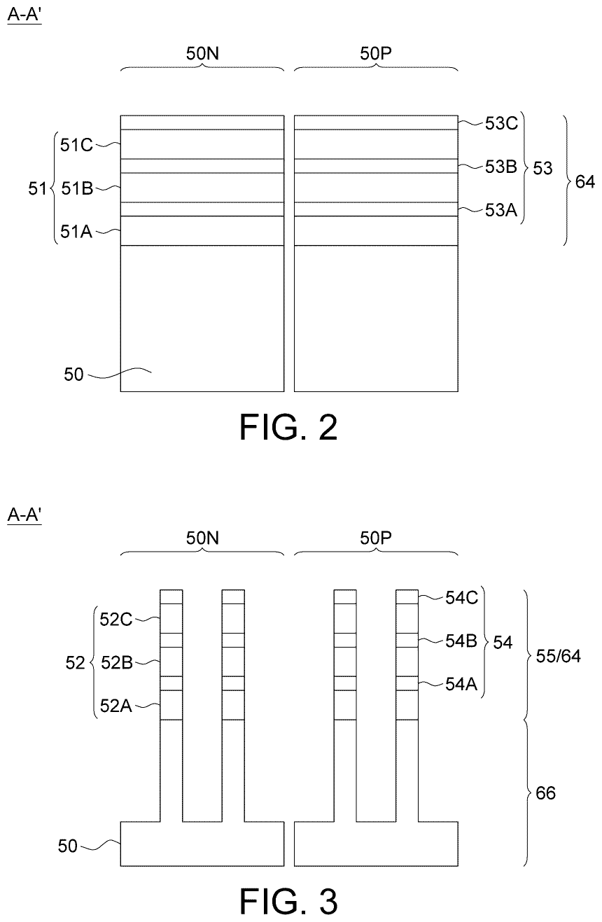

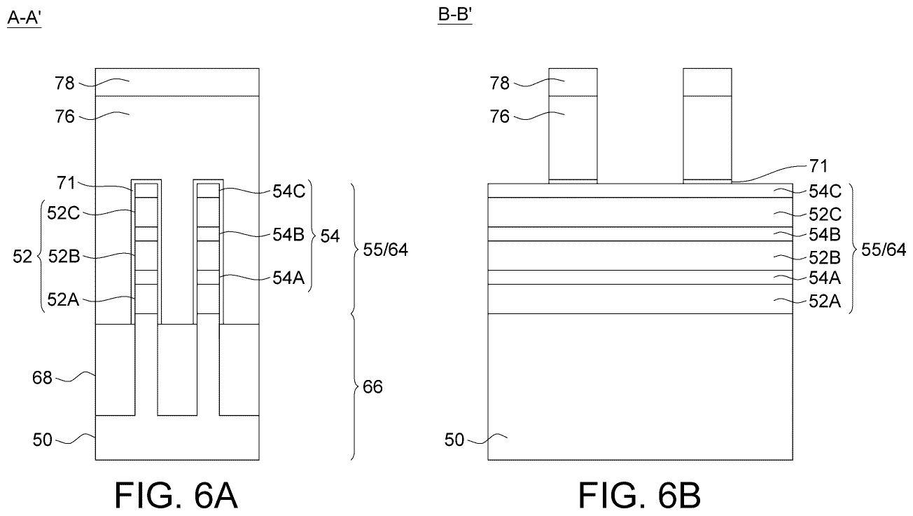

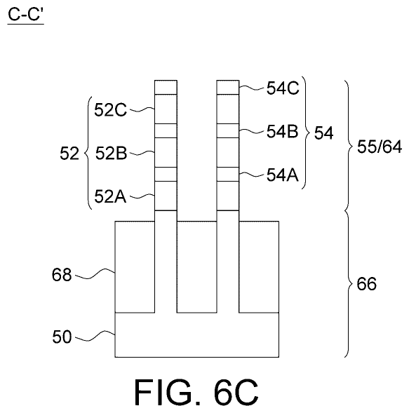

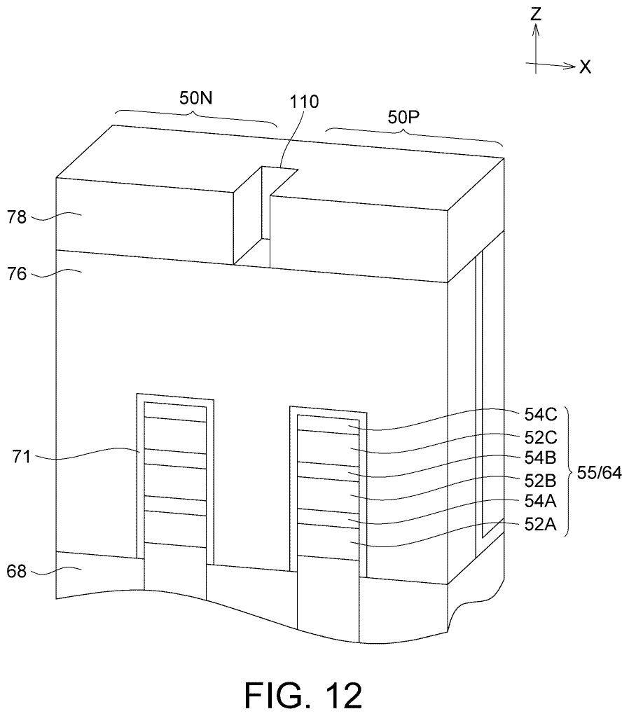

FIGS. 2 through 19 are cross-sectional views of intermediate stages in the manufacturing of nano-FETs, in accordance with some embodiments. FIGS. 2 through 5, 6A, 7A, 8A, 9A, 10A, 11A, 12, 13, 14, 15, 16, 17, 18, and 19 illustrate reference cross-section A-A′ illustrated in FIG. 1. FIGS. 6B, 7B, 8B, 9B, 10B and 11B illustrate reference cross-section B-B′ illustrated in FIG. 1. FIGS. 6C, 7C, 8C and 9C illustrate reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-51C (collectively referred to as first semiconductor layers 51) and second semiconductor layers 53A-53C (collectively referred to as second semiconductor layers 53). For purposes of illustration and as discussed in greater detail below, the first semiconductor layers 51 will be removed and the second semiconductor layers 53 will be patterned to form channel regions of nano-FETs in the n-type region 50N and the p-type region 50P. However, in some embodiments the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P. In some embodiments the second semiconductor layers 53 may be removed and the first semiconductor layers 51 may be patterned to form channel regions of nano-FETs in the n-type region 50N, and the first semiconductor layers 51 may be removed and the second semiconductor layers 53 may be patterned to form channel regions of nano-FETs in the p-type region 50P. In some embodiments, the second semiconductor layers 53 may be removed and the first semiconductor layers 51 may be patterned to form channel regions of nano-FETs in both the n-type region 50N and the p-type region 50P.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material, such as silicon germanium or the like, and the second semiconductor layers 53 may be formed of a second semiconductor material, such as silicon, silicon carbon, or the like. The multi-layer stack 64 is illustrated as having a bottommost semiconductor layer formed of the first semiconductor materials for illustrative purposes. In some embodiments, the multi-layer stack 64 may be formed such that the bottommost layer is formed of the second semiconductor materials.

The first semiconductor materials and the second semiconductor materials may be materials having a high etch selectivity to one another. As such, the first semiconductor layers 51 of the first semiconductor material may be removed without significantly removing the second semiconductor layers 53 of the second semiconductor material thereby allowing the second semiconductor layers 53 to be patterned to form channel regions of nano-FETs. Similarly, in embodiments in which the second semiconductor layers 53 are removed and the first semiconductor layers 51 are patterned to form channel regions, the second semiconductor layers 53 of the second semiconductor material may be removed without significantly removing the first semiconductor layers 51 of the first semiconductor material, thereby allowing the first semiconductor layers 51 to be patterned to form channel regions of nano-FETs.

In FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), a neutral beam etch (NBE), the like, or a combination thereof. The etching may be anisotropic. Forming the nanostructures 55 by etching the multi-layer stack 64 may further define first nanostructures 52A-52C (collectively referred to as the first nanostructures 52) from the first semiconductor layers 51 and define second nanostructures 54A-54C (collectively referred to as the second nanostructures 54) from the second semiconductor layers 53. The first nanostructures 52 and the second nanostructures 54 may be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 3 illustrates the fins 66 in the n-type region 50N and the p-type region 50P as having substantially equal widths for illustrative purposes. In some embodiments, widths of the fins 66 in the n-type region 50N may be greater or thinner than widths of the fins 66 in the p-type region 50P. Further, while each of the fins 66 and the nanostructures 55 are illustrated as having consistent widths throughout, in other embodiments, the fins 66 and/or the nanostructures 55 may have tapered sidewalls such that widths of the fins 66 and/or the nanostructures 55 continuously increases in a direction towards the substrate 50. In such embodiments, each of the nanostructures 55 may have different widths and be trapezoidal in shape.

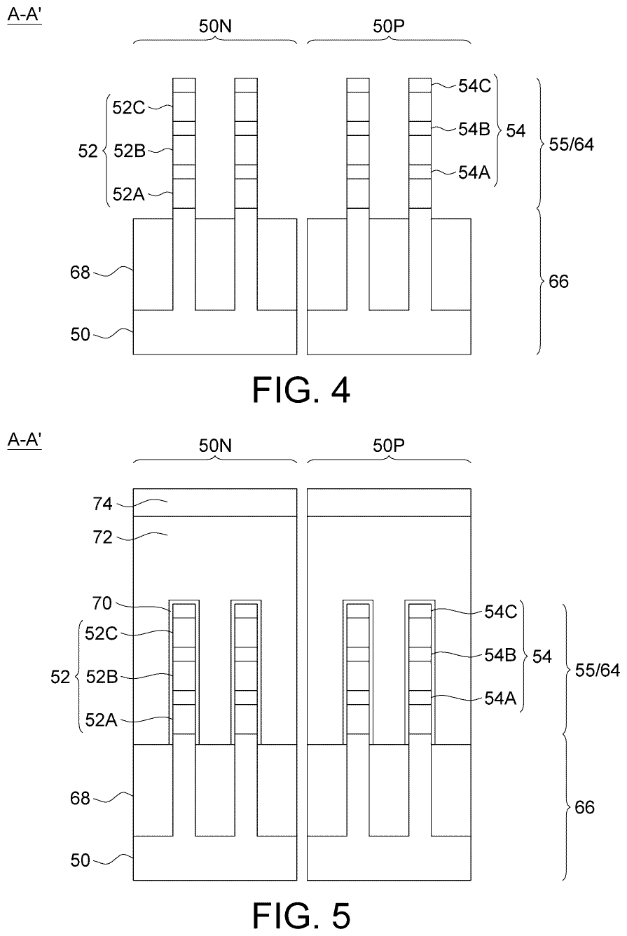

In FIG. 4, shallow trench isolation (STI) regions 68 are formed adjacent the fins 66. The STI regions 68 may be formed by depositing an insulation material over the substrate 50, the fins 66, and the nanostructures 55, and between adjacent ones of the fins 66. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along surfaces of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that the nanostructures 55 and upper portions of fins 66 in the n-type region 50N and the p-type region 50P protrude from between neighboring STI regions 68. Further, the top surfaces of the STI regions 68 may have flat surfaces as illustrated, convex surfaces, concave surfaces (such as dishing), or combinations thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric acid (dHF) may be used.

The process described above with respect to FIGS. 2 through 4 is just one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers 51 (and the resulting first nanostructures 52) and the second semiconductor layers 53 (and the resulting second nanostructures 54) are illustrated and discussed herein as comprising the same materials in the p-type region 50P and the n-type region 50N for illustrative purposes only. In some embodiments, one or both of the first semiconductor layers 51 and the second semiconductor layers 53 may be different materials or formed in a different order in the p-type region 50P and the n-type region 50N.

Further in FIG. 4, appropriate wells (not separately illustrated) may be formed in the fins 66, the nanostructures 55, and/or the STI regions 68. In embodiments with different well types, different implant steps for the n-type region 50N and the p-type region 50P may be achieved using a photoresist or other masks (not separately illustrated). For example, a photoresist may be formed over the fins 66 and the STI regions 68 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66, the nanostructures 55, and the STI regions 68 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

In FIG. 5, a dummy dielectric layer 70 is formed on the fins 66 and/or the nanostructures 55. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity from the etching of isolation regions. The mask layer 74 may include, for example, silicon nitride, silicon oxynitride, or the like. In this example, a single dummy gate layer 72 and a single mask layer 74 are formed across the n-type region 50N and the p-type region 50P. It is noted that the dummy dielectric layer 70 is shown covering only the fins 66 and the nanostructures 55 for illustrative purposes only. In some embodiments, the dummy dielectric layer 70 may be deposited such that the dummy dielectric layer 70 covers the STI regions 68, such that the dummy dielectric layer 70 extends between the dummy gate layer 72 and the STI regions 68.

FIGS. 6A through 26B illustrate various additional steps in the manufacturing of embodiment devices. FIGS. 6A through 26B illustrate features in either the n-type region 50N or the p-type region 50P. In FIGS. 6A through 6C, the mask layer 74 (see FIG. 5) may be patterned using acceptable photolithography and etching techniques to form masks 78. The pattern of the masks 78 then may be transferred to the dummy gate layer 72 and to the dummy dielectric layer 70 to form dummy gates 76 and dummy gate dielectrics 71, respectively. The dummy gates 76 cover respective channel regions of the fins 66 and portions of the second nanostructures 54, which form channel regions. The pattern of the masks 78 may be used to separate each of the dummy gates 76 from adjacent dummy gates 76. The dummy gates 76 may have lengthwise directions perpendicular to lengthwise directions of respective ones of the fins 66.

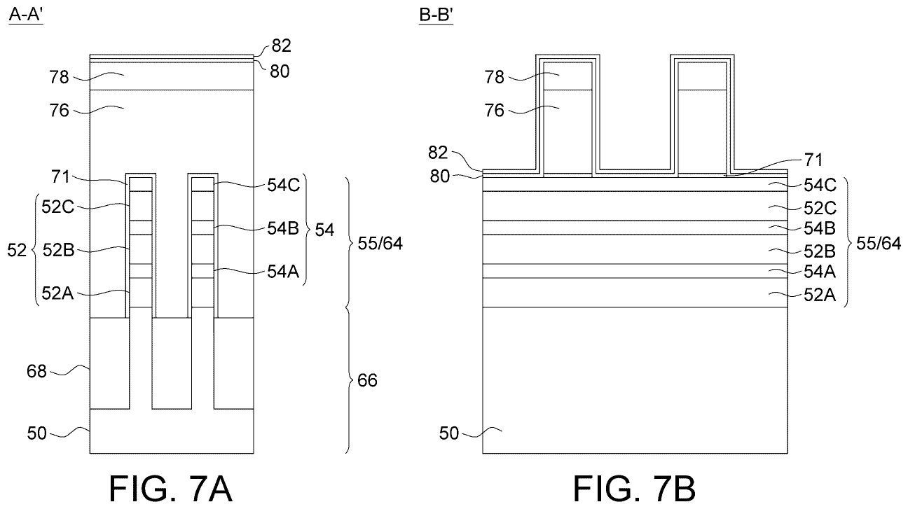

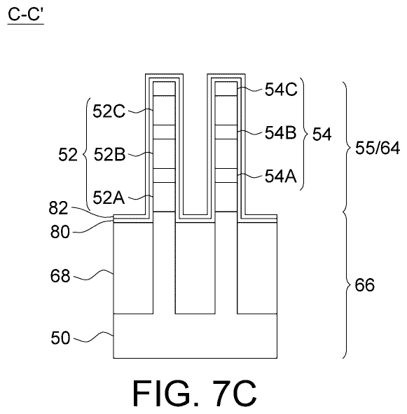

In FIGS. 7A through 7C, a first spacer layer 80 and a second spacer layer 82 are formed over the structures illustrated in FIGS. 6A through 6C. The first spacer layer 80 and the second spacer layer 82 will be subsequently patterned to act as spacers for forming self-aligned source/drain regions. In FIGS. 7A through 7C, the first spacer layer 80 is formed on top surfaces of the STI regions 68; side surfaces of the fins 66, the dummy gate dielectrics 71, and the dummy gates 76; and top surfaces and side surfaces of the nanostructures 55 and the masks 78. The second spacer layer 82 is deposited over the first spacer layer 80. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like. The first spacer layer 80 and the second spacer layer 82 may comprise low-k dielectric materials.

After the first spacer layer 80 is formed and prior to forming the second spacer layer 82, implants for lightly doped source/drain (LDD) regions (not separately illustrated) may be performed. In embodiments with different device types, similar to the implants discussed above in FIG. 4, a mask, such as a photoresist, may be formed over the n-type region 50N, while exposing the p-type region 50P, and appropriate type (e.g., p-type) impurities may be implanted into the exposed fins 66 and the exposed nanostructures 55 in the p-type region 50P. The mask may then be removed. Subsequently, a mask, such as a photoresist, may be formed over the p-type region 50P while exposing the n-type region 50N, and appropriate type (e.g., n-type) impurities may be implanted into the exposed fins 66 and the exposed nanostructures 55 in the n-type region 50N. The mask may then be removed. The n-type impurities may be the any of the n-type impurities previously discussed and the p-type impurities may be the any of the p-type impurities previously discussed. The lightly doped source/drain regions may have a concentration of impurities in a range from about 1×10¹⁵ atoms/cm³ to about 1×10¹⁹ atoms/cm³. An anneal may be used to repair implant damage and to activate the implanted impurities.

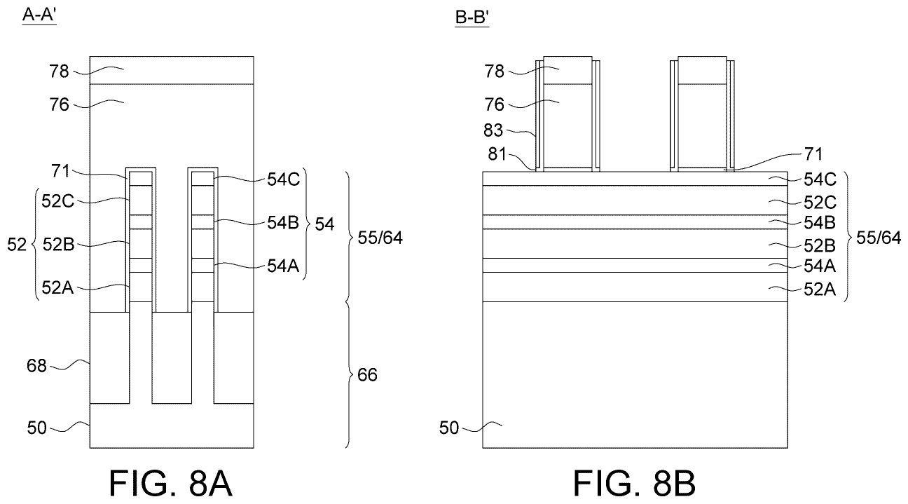

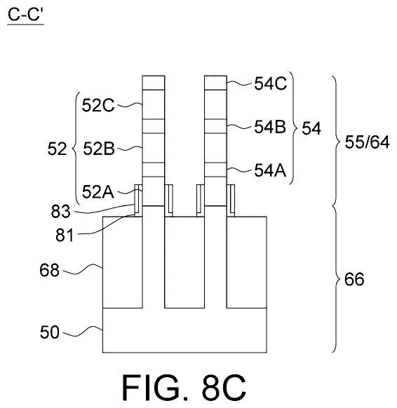

In FIGS. 8A through 8C, the first spacer layer 80 and the second spacer layer 82 are etched to form first spacers 81 and second spacers 83, respectively. As will be discussed in greater detail below, the first spacers 81 and the second spacers 83 act to self-align subsequently formed source/drain regions, as well as to protect sidewalls of the fins 66 and/or the nanostructures 55 during subsequent processing. The first spacer layer 80 and the second spacer layer 82 may be etched using suitable etching processes, such as isotropic etching processes (e.g., wet etching processes), anisotropic etching processes (e.g., dry etching processes), or the like. In some embodiments, the material of the second spacer layer 82 has a different etch rate than the material of the first spacer layer 80, such that the first spacer layer 80 may act as an etch stop layer when patterning the second spacer layer 82. The second spacer layer 82 may act as a mask when patterning the first spacer layer 80. For example, the second spacer layer 82 may be etched using an anisotropic etch process in which the first spacer layer 80 acts as an etch stop layer. Remaining portions of the second spacer layer 82 form the second spacers 83, as illustrated in FIGS. 8B and 8C. The second spacers 83 then act as a mask while etching exposed portions of the first spacer layer 80 forming the first spacers 81, as illustrated in FIGS. 8B and 8C.

As illustrated in FIG. 8B, the first spacers 81 and the second spacers 83 are disposed on sidewalls of the masks 78, the dummy gates 76, and the dummy gate dielectrics 71. In some embodiments, top surfaces of the first spacers 81 and the second spacers 83 may be disposed below top surfaces of the masks 78. The top surfaces of the first spacers 81 and the second spacers 83 may be disposed level with or above the top surfaces of the masks 78. In some embodiments, the second spacers 83 may be removed from over the first spacers 81 adjacent the masks 78, the dummy gates 76, and the dummy gate dielectrics 71. As illustrated in FIG. 8C, the first spacers 81 and the second spacers 83 are disposed on sidewalls of the fins 66 and/or nanostructures 55.

It is noted that the above disclosure generally describes a process of forming spacers and LDD regions. Other processes and sequences may be used. For example, fewer or additional spacers may be utilized, different sequence of steps may be utilized (e.g., the first spacers 81 may be patterned prior to depositing the second spacer layer 82), additional spacers may be formed and removed, and/or the like. Furthermore, the n-type and p-type devices may be formed using different structures and steps.

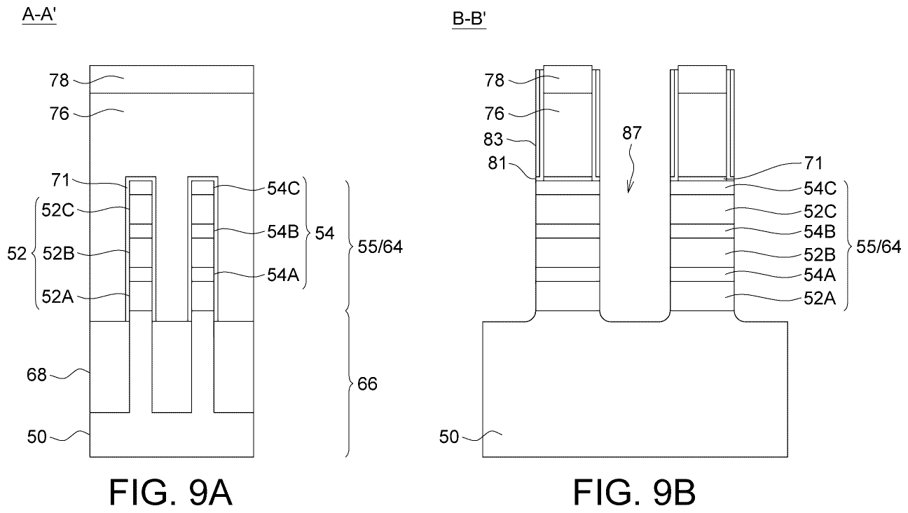

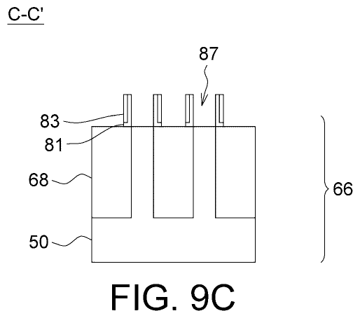

In FIGS. 9A through 9C, first recesses 87 are formed in the fins 66, the nanostructures 55, and the substrate 50. Epitaxial source/drain regions will be subsequently formed in the first recesses 87. The first recesses 87 may extend through the first nanostructures 52 and the second nanostructures 54, and into the substrate 50. In some embodiments, top surfaces of the STI regions 68 may be level with bottom surfaces of the first recesses 87. In some embodiments, the top surfaces of the STI regions 68 may be above or below the bottom surfaces of the first recesses 87. The first recesses 87 may be formed by etching the fins 66, the nanostructures 55, and the substrate 50 using anisotropic etching processes, such as RIE, NBE, or the like. The first spacers 81, the second spacers 83, and the masks 78 mask portions of the fins 66, the nanostructures 55, and the substrate 50 during the etching processes used to form the first recesses 87. A single etch process or multiple etch processes may be used to etch each layer of the nanostructures 55 and/or the fins 66. Timed etch processes may be used to stop the etching after the first recesses 87 reach desired depths.

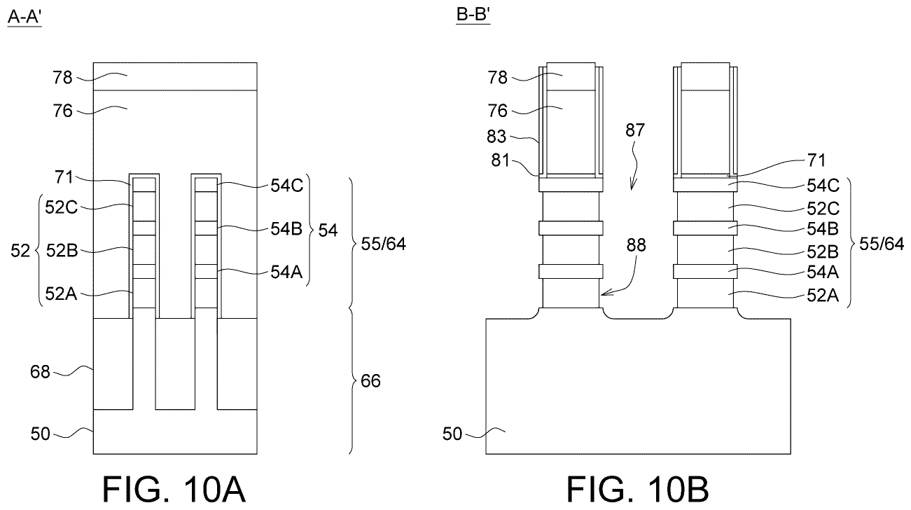

In FIGS. 10A and 10B, portions of sidewalls of the layers of the multi-layer stack 64 formed of the first semiconductor materials (e.g., the first nanostructures 52) exposed by the first recesses 87 are etched to form sidewall recesses 88. Although sidewalls of the first nanostructures 52 adjacent the sidewall recesses 88 are illustrated as being straight in FIG. 10B, the sidewalls may be concave or convex. The sidewalls may be etched using isotropic etching processes, such as wet etching or the like. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to etch sidewalls of the first nanostructures 52.

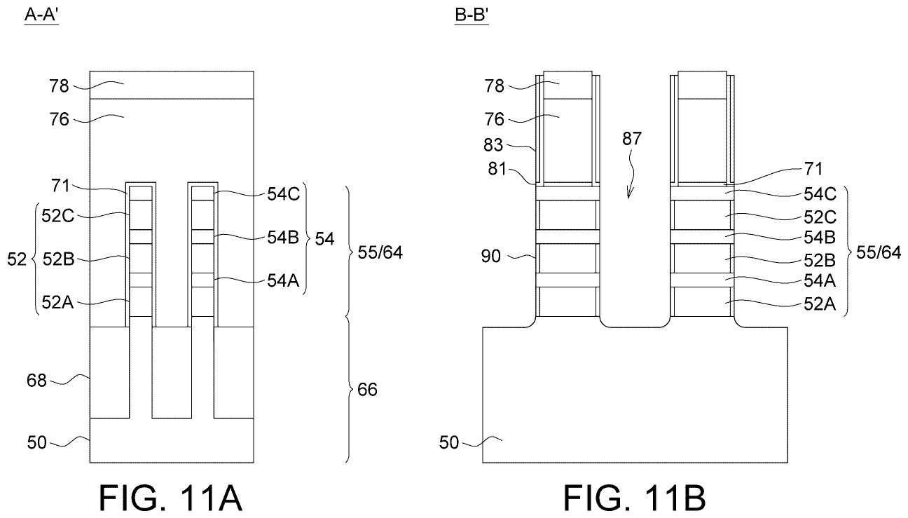

In FIGS. 11A through 11B, first inner spacers 90 are formed in the sidewall recess 88. The first inner spacers 90 may be formed by depositing an inner spacer layer (not separately illustrated) over the structures illustrated in FIGS. 10A and 10B. The first inner spacers 90 act as isolation features between subsequently formed source/drain regions and subsequently formed gate structures. As will be discussed in detail below, the source/drain regions will be formed in the first recesses 87, while the first nanostructures 52 will be replaced with the gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the first inner spacers 90. Although outer sidewalls of the first inner spacers 90 are illustrated as flush with sidewalls of the second nanostructures 54, the outer sidewalls of the first inner spacers 90 may extend beyond or be recessed from sidewalls of the second nanostructures 54.

Moreover, although the outer sidewalls of the first inner spacers 90 are illustrated as straight in FIG. 11B, the outer sidewalls of the first inner spacers 90 may be concave or convex. The inner spacer layer may be etched by an anisotropic etching process, such as RIE, NBE, or the like. The first inner spacers 90 may be used to prevent damage to subsequently formed source/drain regions (such as the epitaxial source/drain regions 92, discussed with respect to FIG. 1) by subsequent etching processes, such as etching processes used to form gate structures.

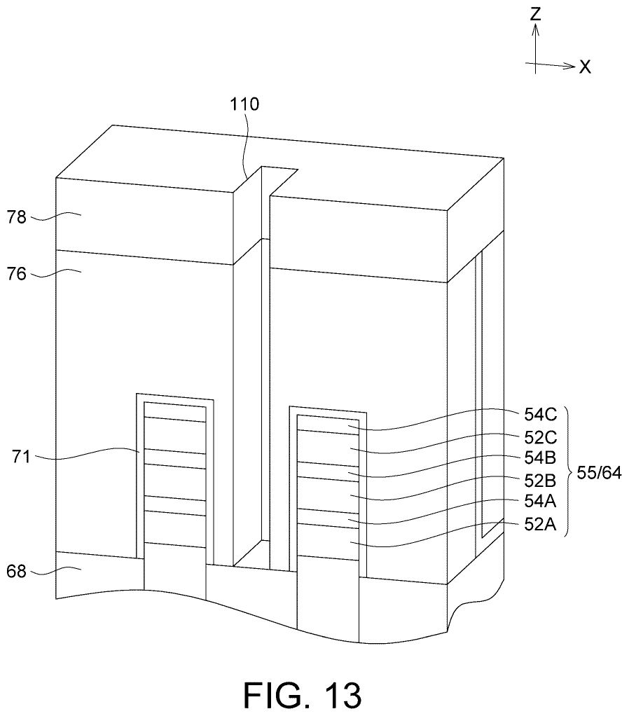

In FIG. 13, the dummy gates 76 and the masks 78 are partially etched to form a recess 110 with high aperture ratio. The recess 110 extends along the vertical direction of the dummy gates 76 and the masks 78 and is formed between two adjacent nanostructures 55, such as between n-type devices with NMOS transistors, e.g., n-type nano-FETs, and p-type devices with PMOS transistors, e.g., p-type nano-FETs.

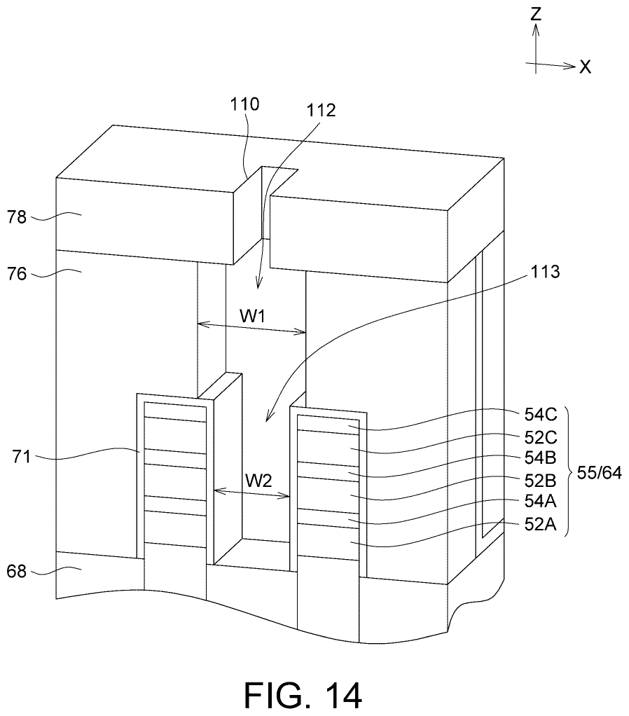

In FIG. 14, the dummy gates 76 are further etched to form a recess 110 with an enlarged opening 112 on the top of the nanostructures 55 and a narrow opening 113 between the nanostructures 55. The enlarged opening 112 has a first width W1 in the second direction (i.e. X-cut direction) and the narrow opening 113 on the bottom of the recess 110 has a second width W2 in the same direction. The second width W2 is less than the first width W1 so that a portion of the dummy gate dielectrics 71 on the top of the nanostructures 55 is exposed from the enlarged opening 112. In addition, another portion of the dummy gate dielectrics 71 on opposite sides of the nanostructures 55 is exposed from the narrow opening 113. In some embodiment, the first width W1 may be between 35 nm and 55 nm, and the first width W2 may be between 35 nm and 50 nm. The width of two adjacent fins 66 may be between 30 nm and 45 nm.

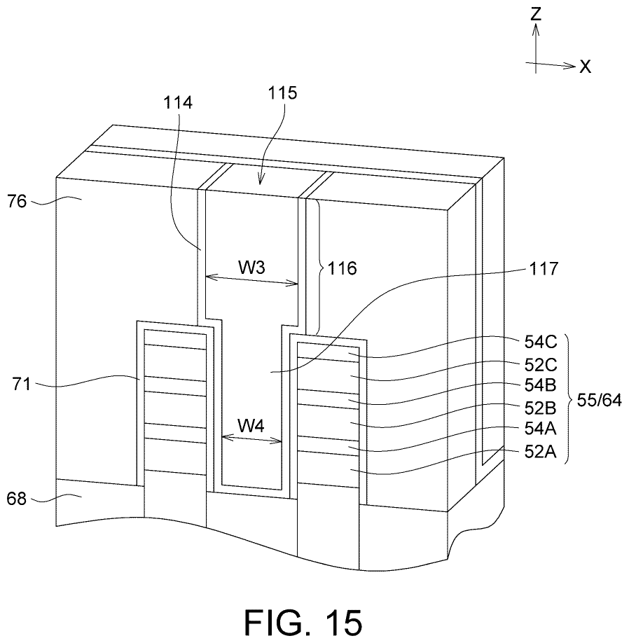

In FIG. 15, the masks 78 are removed and a liner 114 is formed in the recess 110. The liner 114 is deposited on the sidewalls and the bottom surface of the recess 110. That is, the liner 114 covers the exposed portion of the dummy gate dielectrics 71 and the dummy gates 76. In FIG. 14, a dielectric wall 115 is formed in the recess 110 after the liner 114 is formed. The dielectric wall 115 has an enlarged wall 116 corresponding to the enlarged opening 112 of the recess 110 and a narrow wall 117 corresponding to the narrow opening 113 of the recess 110. The width W3 of the enlarged wall 116 is greater than the width W4 of the narrow wall 117. The dielectric wall 115 is formed for separating from the two adjacent nanostructures 55 so that the parasitic capacitance induced by EPI/metal gate structure between the nanostructures 55 can be reduced. In some embodiment, the width W3 may be between 35 nm and 55 nm, and the width W4 may be between 35 nm and 50 nm. The width of two adjacent fins 66 may be between 30 nm and 45 nm.

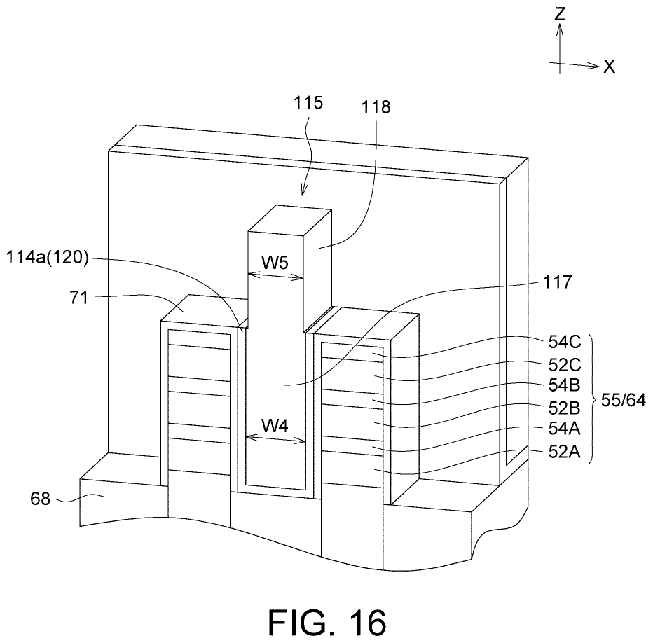

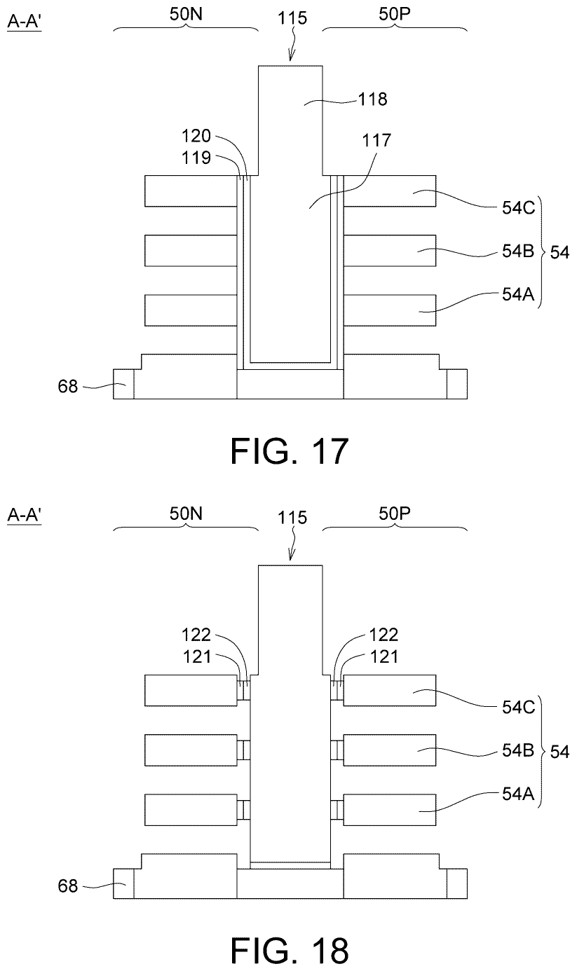

In FIG. 16, the dummy gates 76 are removed in one or more etching steps. Portions of the liner 114 and the dielectric wall 115 in the recess 110 are also be removed. In some embodiments, the dummy gates 76 and the liner 114 are removed by an anisotropic dry etch process. For example, the etching process may include a dry etch process using reaction gas(es) that selectively etch the dummy gates 76 at a faster rate than the first spacers 81, the second spacers 83, the nanostructures 55, or the STI regions 68. During the removal of the dummy gates 76 and the liner 114, the dummy gate dielectrics 71 may be used as etch stop layers when the dummy gates 76 are etched. Portions of the dummy gate dielectrics 71 and liner 114 may then be removed after the removal of the dummy gates 76, while the un-etched portion 119 of the dummy gate dielectrics 71 and the un-etched liner 114a may remain to form two wall spacer layers in FIG. 17.

In FIG. 16, the enlarged wall 116 of the dielectric wall 115 may be trimmed by etching process to form a top trimmed portion 118 with a width W5 less than a width W4 of the lower portion of the dielectric wall 115 (i.e., the narrow wall 117). That is, the top trimmed portion 118 is thinner than the lower portion so that the un-etched liner 114a disposed between the narrow wall 117 and the nanostructures 55 is exposed from the dielectric wall 115. As shown in FIG. 17, after the dummy gate dielectrics 71 are removed, the first nanostructures 52 are removed to expose the top surfaces and bottom surfaces of the second nanostructures 54. In some embodiment, the width W5 may be between 30nm and 40nm, and the width W4 may be between 35 nm and 50 nm. The width of two adjacent fins 66 may be between 30 nm and 45 nm.

In FIG. 17, the first nanostructures 52 may be removed by performing an isotropic etching process such as wet etching or the like using etchants selective to the materials of the first nanostructures 52, while the second nanostructures 54, the substrate 50, and the STI regions 68 remain relatively un-etched as compared to the first nanostructures 52. In embodiments in which the first nanostructures 52 include, e.g., SiGe, and the second nanostructures 54 include, e.g., Si or SiC, tetramethylammonium hydroxide (TMAH), ammonium hydroxide (NH₄OH), or the like may be used to remove the first nanostructures 52.

In FIG. 17, when the first nanostructures 52 are removed, the dummy gate dielectrics 71 remains un-etched to form a first wall spacer layer 119 on the sides of the second nanostructures 54, and the liner 114a remains un-etched to form a second wall spacer layer 120 between the first wall spacer layer 119 and the dielectric wall 115.

In FIG. 18, portion of the first wall spacer layer 119 may be removed by performing an isotropic etching process such as wet etching or the like, and other portion of the first wall spacer layer 119 remain un-etched to form a first wall spacer 121 on the sides of the second nanostructures 54. In addition, portion of the second wall spacer layer 120 may be removed by performing an isotropic etching process such as wet etching or the like, and other portion of the second wall spacer layer 120 remain un-etched to form a second wall spacer 122 between the first wall spacer 121 and the dielectric wall 115.

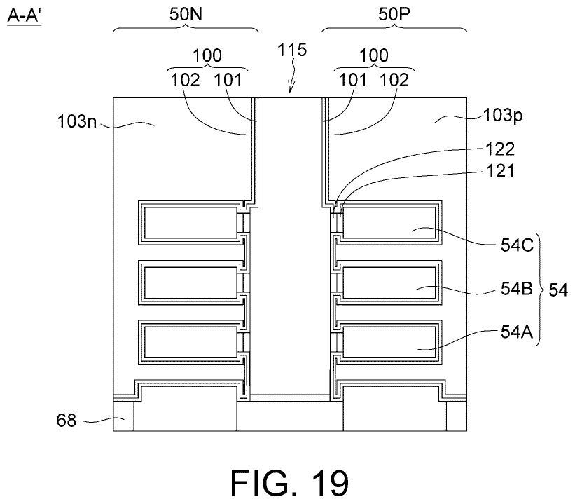

In FIG. 19, gate dielectric layers 100 are deposited conformally in the spaces between the second nanostructures 54 in the n-type region 50N and the p-type region 50P. The gate dielectric layers 100 may be formed on top surfaces and side surfaces of the fins 66 and on top surfaces, side surfaces, and bottom surfaces of the second nanostructures 54. The gate dielectric layers 100 may also be deposited on top surfaces of the second spacers 83, and the STI regions 68; on top surfaces and side surfaces of the first spacers 81; and on side surfaces of the first inner spacers 90 (shown in FIG. 11B). The gate dielectric layers 100 comprise one or more dielectric layers, such as an oxide, a metal oxide, the like, or combinations thereof. In some embodiments, the gate dielectric layers 100 may comprise first gate dielectric layers 101 (e.g., comprising silicon oxide or the like) and second gate dielectric layers 102 (e.g., comprising a metal oxide or the like) of high-k dielectric material. In some embodiments, the second gate dielectric layers 102 may have a k-value greater than about 7.0, and may include a metal oxide or a silicate of hafnium, alumium, zirconium, lanthanum, manganese, barium, titanium, lead, and combinations thereof. The first gate dielectric layers 101 may be referred to as interfacial layers, and the second gate dielectric layers 102 may be referred to as high-k gate dielectric layers, in some embodiments.

The structure of the gate dielectric layers 100 may be the same or different in the n-type region 50N and the p-type region 50P. For example, the p-type region 50P may be masked or exposed while forming the gate dielectric layers 100 in the n-type region 50N. In embodiments where the p-type region 50P is exposed, the gate dielectric layers 100 may be simultaneously formed in the p-type regions 50P. The formation methods of the gate dielectric layers 100 may include molecular-beam deposition (MBD), ALD, CVD, PVD, and the like.

In FIG. 19, a first conductive material 103n is formed over the gate dielectric layers 100 in the n-type region 50N. In FIG. 19, a second conductive material 103p is also formed over the gate dielectric layers 100 in the p-type region 50P. The first and second conductive materials 103n and 103p are separated by the dielectric structure (i.e., dielectric wall). In some embodiments, the first conductive material 103n and the second conductive material 103p may be gate electrode layers having a π-shape in a cross-sectional view along the second direction (i.e., X-cut direction).

The first and second conductive materials 103n and 103p may fill the spaces between the second nanostructures 54 and extend over the gate dielectric layers 100. The first and second conductive materials 103n and 103p may be deposited conformally by a process such as ALD, CVD, PVD, or the like. In some embodiments, the first and second conductive materials 103n and 103p is a p-type work function layer and a n-type work function layer respectively, which may comprise W, Cu, TiN, Ti, Pt, Ta, TaN, Co, Ni, TaC, TaCN, TaSiN, TaSi₂, NiSi₂, Mn, Zr, ZrSi₂, TaN, Ru, Mo, MoSi₂, WN, WCN, other metal oxides, metal nitrides, metal silicates, transition metal-oxides, transition metal-nitrides, transition metal-silicates, oxynitrides of metals, metal aluminates, zirconium silicate, zirconium aluminate, combination thereof, or the like. After filling of the first and second conductive materials 103n and 103p over the second nanostructures 54, a planarization process, such as a CMP, may be performed to remove the excess portions of the first and second conductive materials 104n and 103p, which excess portions are over the top surface of the ILD layer, the first spacers 81, and the second spacers 83. The bottom surface of the second conductive material 103p in p-type region 50P may be level with or lower than the bottom surface of the first conductive material 103n in n-type region 50N.

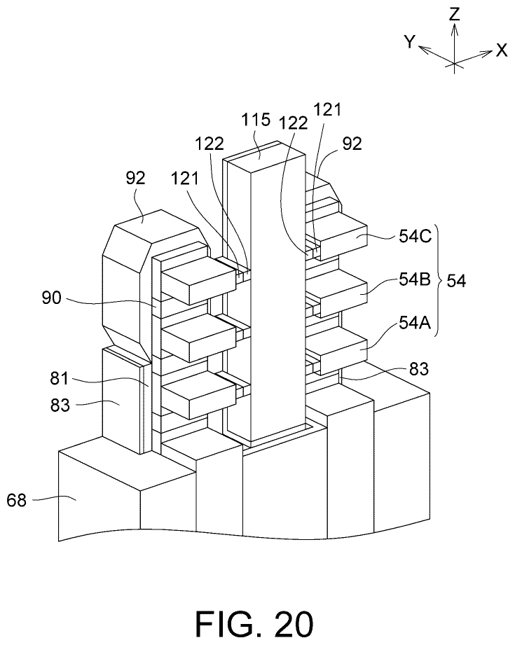

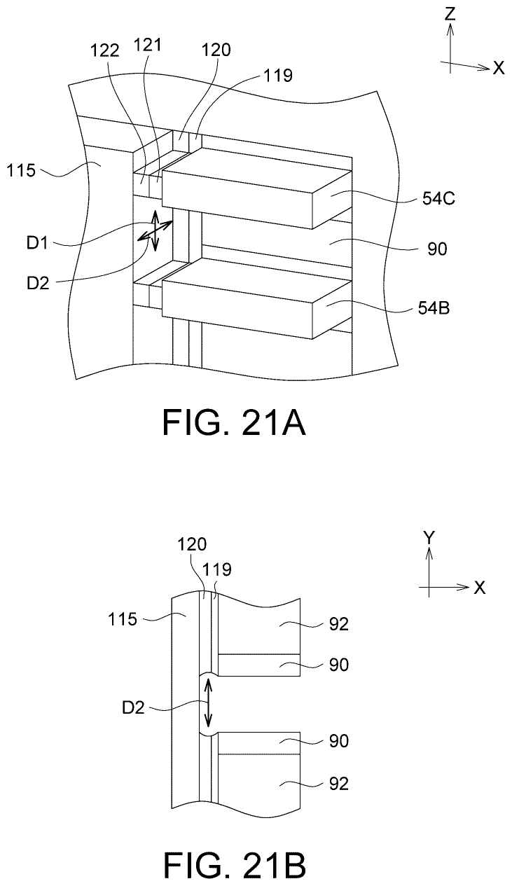

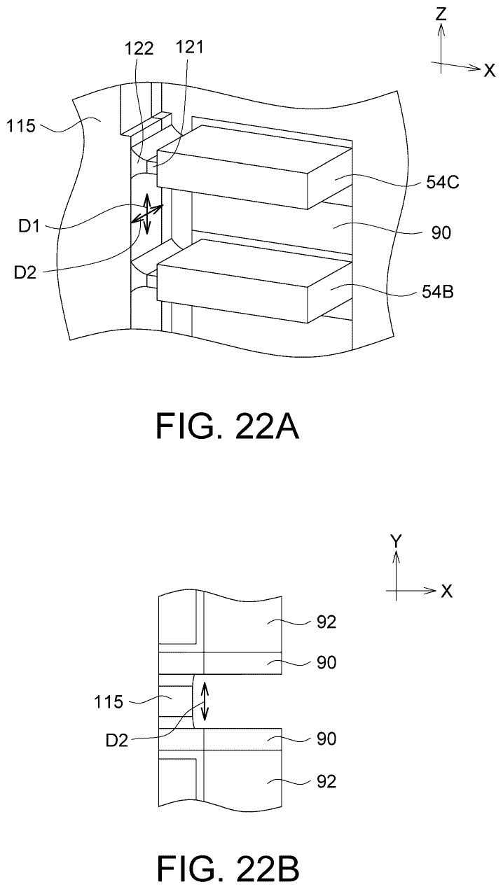

FIG. 20 illustrates an example of a nanostructure field-effect transistor (nano-FET) in a three-dimensional view, in accordance with some embodiments. FIGS. 21A and 21B illustrate an example of nano-FETs of FIG. 20 in a three-dimensional view and a top view, respectively. FIGS. 22A and 22B illustrate another example of nano-FETs of FIG. 20 in a three-dimensional view and a top view, respectively.

In FIG. 20, the epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the recesses 87 of the n-type region 50N. The epitaxial source/drain regions 92 may include any acceptable material appropriate for n-type nano-FETs. For example, if the second nanostructures 54 are silicon, the epitaxial source/drain regions 92 may include materials exerting a tensile strain on the second nanostructures 54, such as silicon, silicon carbide, phosphorous-doped silicon carbide, silicon phosphide, or the like. The epitaxial source/drain regions 92 may have surfaces raised from respective upper surfaces of the second nanostructures 54 and may have facets.

The epitaxial source/drain regions 92 in the p-type region 50P, e.g., the PMOS region, may be formed by masking the n-type region 50 N, e.g., the NMOS region. Then, the epitaxial source/drain regions 92 are epitaxially grown in the recesses 87 of the p-type region 50P. The epitaxial source/drain regions 92 may include any acceptable material appropriate for p-type nano-FETs. For example, if the second nanostructures 54 are silicon, the epitaxial source/drain regions 92 may comprise materials exerting a compressive strain on the second nanostructures 54, such as silicon-germanium, boron doped silicon-germanium, germanium, germanium tin, or the like. The epitaxial source/drain regions 92 may also have surfaces raised from respective upper surfaces of the second nanostructures 54 and may have facets.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, the facets cause adjacent epitaxial source/drain regions 92 of a same nano-FET to merge. In some embodiments, adjacent epitaxial source/drain regions 92 remain separated after the epitaxy process is completed as illustrated by FIG. 20. In the embodiments illustrated in FIG. 20, the first spacers 81 may be formed over top surfaces of the STI regions 68 and may block the epitaxial growth. In some embodiments, the first spacers 81 may cover portions of sidewalls of the second nanostructures 54, further blocking the epitaxial growth. In some embodiments, the spacer etch used to form the first spacers 81 may be adjusted to remove the spacer material to allow the epitaxial source/drain regions 92 to extend to the top surfaces of the STI regions 68.

The epitaxial source/drain regions 92 may comprise one or more semiconductor material layers. For example, the epitaxial source/drain regions 92 may comprise a first semiconductor material layer, a second semiconductor material layer, and a third semiconductor material layer. Any number of semiconductor material layers may be used for the epitaxial source/drain regions 92. Each of the first semiconductor material layer, the second semiconductor material layer, and the third semiconductor material layer may be formed of different semiconductor materials and may be doped to different dopant concentrations. In some embodiments, the first semiconductor material layer may have a dopant concentration less than the second semiconductor material layer and greater than the third semiconductor material layer. In embodiments in which the epitaxial source/drain regions 92 comprise three semiconductor material layers, the first semiconductor material layer may be deposited, the second semiconductor material layer may be deposited over the first semiconductor material layer, and the third semiconductor material layer may be deposited over the second semiconductor material layer.

In FIGS. 21A and 21B, portions of the first and second wall spacer layers 119 and 120 are etched along the first etching direction D1 and second etching direction D2 to form the first and second wall spaces 121 and 122, while other portions of the first and second wall spacer layers 119 and 120 remain un-etched in the second etching direction D2 so that the profile of the un-etched first and second wall spacer layers 121 and 122 may be concave shape. In FIGS. 22A and 22B, the profile of the first and second wall spacers 121 and 122 may be arc-shaped in the first etching direction D1, while the dielectric wall 115 remains un-etched to have a straight profile in the first and second etching directions D1 and D2. In some embodiments, the width of the first wall spacer 121 may be less than the width of the second wall spacer 122 to form a taper shape in the first etching direction D1.

In one embodiment, the first wall spacer 121 may be silicon oxide, and the second wall spacer 122 may be silicon nitride or silicon carbon nitride with a thickness of about 3 nm. The dielectric wall 115 may be silicon nitride, silicon carbon nitride, or silicon-oxycarbide with a thickness of about 15-25 nm or less than 15 nm.

The present disclosure is directed to improve the performance of the nano-FET. The dielectric structure is formed for separating two adjacent nanostructures from each other so that the parasitic capacitance induced by epitaxial/metal gate structure between the nanostructures can be reduced. In some embodiments, the dielectric structure is disposed between the first and second channel regions, the first channel region is disposed in n-type region for forming n-type devices, such as NMOS transistors, and the second channel region is disposed in p-type region for forming p-type devices, such as PMOS transistors.

According to some embodiments, the present disclosure provides a semiconductor device comprising a first channel region (i.e., nanostructures 55), a second channel region (i.e., nanostructures 55), and a dielectric structure. The first channel region extends over a semiconductor substrate 50. The second channel region extends over the semiconductor substrate and is parallel to the first channel region in a first direction (i.e. Y-cut direction). The dielectric structure is disposed between the first and second channel regions, wherein the dielectric structure comprises a dielectric wall 115 and at least two wall spacers, the two wall spacers are disposed on opposite sides of the dielectric wall 115 and connected to the first channel region and the second channel region, respectively.

In some embodiments, the semiconductor device further comprises a first gate structure covering the first channel region in a second direction (i.e. X-cut direction) perpendicular to the first direction, and the first gate structure is disposed at one side of the wall structure.

In some embodiments, the semiconductor device further comprises a second gate structure covering the second channel region in the second direction (i.e. Y-cut direction), and the second gate structure is disposed at another side of the wall structure, wherein the first and second gate structures are separated by the wall structure.

In some embodiments, each of the first and second gate structures has a π-shape in a cross-sectional view along the section direction.

In some embodiments, the first gate structure comprises an n-type work-function layer (i.e. the first conductive material 103n), and the second gate structure comprises a p-type work-function layer (i.e. the second conductive material 103p).

In some embodiments, each of the two spacers comprise a first wall spacer 121 and a second wall spacer 122, wherein the first wall spacer 121 is disposed between the first/second channel region and the second wall spacer 122, and the second wall spacer 122 is disposed between the first wall spacer 121 and the dielectric wall 115.

According to some embodiments, the present disclosure provides a semiconductor device comprising a first channel region (i.e., nanostructures 55), a second channel region (i.e., nanostructures 55), and a dielectric structure. The first channel region extends over a semiconductor substrate 50. The second channel region extends over the semiconductor substrate and is parallel to the first channel region in a first direction (i.e. Y-cut direction). The dielectric structure is disposed between the first and second channel regions, wherein the dielectric structure comprises a dielectric wall 115 and at least two wall spacers, the two wall spacers are disposed on opposite sides of the dielectric wall 115 and connected to the first channel region and the second channel region, respectively. The dielectric wall 115 has a top trimmed wall 118 and a lower portion, and a width W5 of the top trimmed portion 118 is less than a width W4 of the lower portion in a second direction (i.e. X-cut direction) perpendicular to the first direction.

In some embodiments, the width of the top trimmed portion 118 is between 30 nm and 40 nm, and the width of the bottom portion is between 35 nm and 50 nm.

According to some embodiments, the present disclosure provides a method for manufacturing a semiconductor device, which comprises the following steps. A first channel region (i.e., nanostructures 55) is formed in an n-type region 50n of a semiconductor substrate 50. A second channel region (i.e., nanostructures 55) is formed in a p-type region 50p of the semiconductor substrate 50 and the second channel region is parallel to the first channel region in a first direction (i.e. Y-cut direction). The dielectric structure is formed between the first and second channel regions, wherein the dielectric structure comprises a dielectric wall 115 and at least two wall spacers, the two wall spacers are disposed on opposite sides of the dielectric wall 115 and connected to the first channel region and the second channel region, respectively.

In some embodiments, the dielectric structure is formed by the following steps. A dummy dielectric layer 70 is deposited on the n-type region 50n and the p-type region 50p. A dummy gate layer 76 is deposited over the dummy dielectric layer 70. A mask layer 78 is formed over the dummy gate layer 76. the dummy gate layer 76 and the mask layer 78 is partially etched to form a recess 110, and the recess 110 has an enlarged opening 112 on an upper portion of the recess 110 and a narrow opening 113 on a lower portion of the recess 110. A liner 114 is formed in the recess 110 to cover the sidewalls of the recess 110. A dielectric wall 115 is formed over the liner 114, wherein the liner 114 separates the dummy dielectric layer 70 from the dielectric wall 115.

In some embodiments, the dielectric structure is formed by the following steps. The dummy gate layer 76 and a portion of the liner 114 deposited on a top enlarged wall 116 of the dielectric wall 115 are removed, wherein the top enlarged wall 116 is corresponding to the enlarged opening 112. The top enlarged wall 116 of the dielectric wall 115 is etched to form a top trimmed portion 118, wherein a width W5 of the top trimmed portion 118 is less than a width W4 of a lower portion of the dielectric wall 115.

In some embodiments, the dielectric structure is formed by the following steps. A portion of the dummy dielectric layer and a portion of the liner 114 deposited on the lower portion of the dielectric wall 115 are removed, and un-etched portions of the dummy dielectric layer 70 and the liner 114 are remained to form at least two wall spacers, wherein the two wall spacers are disposed on opposite sides of the dielectric wall 115 and connected to the first channel region and the second channel region, respectively.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first channel region extending over a semiconductor substrate;
a second channel region extending over the semiconductor substrate and parallel to the first channel region in a first direction; and
a dielectric structure disposed between the first and second channel regions, wherein the dielectric structure comprises a dielectric wall and wall spacers, the wall spacers are disposed on opposite sides of the dielectric wall and connected to the first channel region and the second channel region, respectively.

2. The semiconductor device according to claim 1, further comprising a first gate structure covering the first channel region in a second direction perpendicular to the first direction, and the first gate structure is disposed at one side of the wall structure.

3. The semiconductor device according to claim 2, further comprising a second gate structure covering the second channel region in the second direction, and the second gate structure is disposed at another side of the wall structure, wherein the first and second gate structures are separated by the wall structure.

4. The semiconductor device according to claim 3, wherein each of the first and second gate structures has a π-shape in a cross-sectional view along the section direction.

5. The semiconductor device according to claim 3, wherein the first gate structure comprises an n-type work-function layer, and the second gate structure comprises a p-type work-function layer.

6. The semiconductor device according to claim 1, wherein each of the spacers comprises a first wall spacer and a second wall spacer, wherein the first wall spacer is disposed between the first/second channel region and the second wall spacer, and the second wall spacer is disposed between the first wall spacer and the dielectric wall.

7. A semiconductor device comprising:
a first channel region disposed in an n-type region of a semiconductor substrate;
a second channel region disposed in a p-type region of the semiconductor substrate and parallel to the first channel region in a first direction; and
a dielectric structure disposed between the first and second channel regions, wherein the dielectric structure comprises a dielectric wall and wall spacers, the wall spacers are disposed on opposite sides of the dielectric wall and connected to the first channel region and the second channel region, respectively,
wherein the dielectric wall has a top trimmed wall and a lower portion, and a width of the top trimmed wall is less than a width of the lower portion in a second direction perpendicular to the first direction.

8. The semiconductor device according to claim 7, further comprising a first gate structure covering the first channel region in the second direction, and the first gate structure is disposed at one side of the wall structure.

9. The semiconductor device according to claim 8, further comprising a second gate structure covering the second channel region in the second direction, and the second gate structure is disposed at another side of the wall structure, wherein the first and second gate structures are separated by the wall structure.

10. The semiconductor device according to claim 9, wherein each of the first and second gate structures has a π-shape in a cross-sectional view along the section direction.

11. The semiconductor device according to claim 9, wherein the first gate structure comprises an n-type work-function layer, and the second gate structure comprises a p-type work-function layer.

12. The semiconductor device according to claim 7, wherein each of the wall spacers comprises a first wall spacer and a second wall spacer, wherein the first wall spacer is disposed between the first/second channel region and the second wall spacer, and the second wall spacer is disposed between the first wall spacer and the dielectric wall.

13. The semiconductor device according to claim 7, wherein the width of the top trimmed wall is between 30 nm and 40 nm, and the width of the bottom portion is between 35 nm and 50 nm.

14. A method for manufacturing a semiconductor device comprising:
forming a first channel region in an n-type region of a semiconductor substrate;
forming a second channel region in a p-type region of the semiconductor substrate and the second channel region is parallel to the first channel region in a first direction; and
forming a dielectric structure between the first and second channel regions, wherein the dielectric structure comprises a dielectric wall and wall spacers, the wall spacers are disposed on opposite sides of the dielectric wall and connected to the first channel region and the second channel region, respectively.

15. The method according to claim 14, wherein forming the dielectric structure comprises:
depositing a dummy dielectric layer on the n-type region and the p-type region;
depositing a dummy gate layer over the dummy dielectric layer;
forming a mask layer over the dummy gate layer;
partially etching the dummy gate layer and the mask layer to form a recess, the recess has an enlarged opening on an upper portion of the recess and a narrow opening on a lower portion of the recess;
forming a liner in the recess to cover the sidewalls of the recess; and
forming a dielectric wall over the liner, wherein the liner separates the dummy dielectric layer from the dielectric wall.

16. The method according to claim 15, wherein forming the dielectric structure further comprises:
removing the dummy gate layer and a portion of the liner deposited on a top enlarged portion of the dielectric wall, wherein the top enlarged portion is corresponding to the enlarged opening; and
etching the top enlarged portion of the dielectric wall to form a top trimmed portion, wherein a width of the top trimmed portion is less than a lower portion of the dielectric wall.

17. The method according to claim 16, wherein forming the dielectric structure further comprises:
removing a portion of the dummy dielectric layer and a portion of the liner deposited on the lower portion of the dielectric wall, and remaining un-etched portions of the dummy dielectric layer and the liner to form the wall spacers, wherein the wall spacers are disposed on opposite sides of the dielectric wall and connected to the first channel region and the second channel region, respectively.

18. The method according to claim 17, wherein each of the wall spacers comprises a first wall spacer and a second wall spacer, wherein the first wall spacer is disposed between the first/second channel region and the second wall spacer, and the second wall spacer is disposed between the first wall spacer and the dielectric wall.

19. The method according to claim 17, further comprising:
forming a first gate structure to cover the first channel region in the second direction, and the first gate structure is disposed at one side of the wall structure;
forming a second gate structure to cover the second channel region in the second direction, and the second gate structure is disposed at another side of the wall structure, wherein the first and second gate structures are separated by the wall structure.

20. The method according to claim 19, wherein each of the first and second gate structures has a π-shape in a cross-sectional view along the second direction.
